(19) United States
(12) Patent Application Publication
(10) Pub. No.: US 2008/0023056 A1
(43) Pub. Date: Jan. 31, 2008

(54) Thermoelectric Conversion System and of Increasing Efficiency of Thermoelectric Conversion System

(76) Inventors: Mitsuru Kambe, Tokyo (JP); Hideo Shikata, Chiba (JP)

Correspondence Address: NOTARO AND MICHALOS, 100 DUTCH HILL ROAD, SUITE 110, ORANGEBURG, NY, 10962-2100, US

(21) Appl. No.: 11/596,517

(22) PCT Filed: May 19, 2005
(86) PCT No.: PCT/JP05/09189

§ 371 Date: Nov. 15, 2006

(30) Foreign Application Priority Data
May 19, 2004 (JP) 2004-148987

(51) Int. Cl. H01L 35/30; H01L 35/32; H01L 35/34

(52) U.S. Cl. 136/201; 136/208

(57) ABSTRACT

The present invention relates to a thermoelectric conversion system for receiving heat by radiation from a heat source and an efficiency improving method of the thermoelectric conversion system, the system including at least one thermoelectric conversion module 5 having at least a pair of thermoelectric elements 2, a heat receiving zone 6 placed not to contact a heat source 3 for receiving heat by radiation from the heat source 3 and a radiating zone 7 positioned on an opposite side to the heat receiving zone 6 and cooled by a coolant 4, generating electric power by a temperature difference between the heat receiving zone 6 and the radiating zone 7, a continuous or divided heat receiving surface 18 formed by one or a plurality of surfaces facing the heat source 3 of the heat receiving zone 6, and each of the heat receiving surface 18 is given a different quantity of heat from the heat source 3, the system comprising the heat receiving surface 18 has a plurality of different emissivities according to the quantity of heat received from the heat source 3.

### TECHNICAL FIELD

The present invention relates to a thermoelectric conversion system for receiving heat by radiation from a heat source and an efficiency improving method of the thermoelectric conversion system. To describe it further in detail, the present invention relates to the thermoelectric conversion system suitable for use as a thermoelectric conversion system of which heat source is waste heat generated by a sintering furnace, iron or non-ferrous metal manufacturing plants and the like and the efficiency improving method of the thermoelectric conversion system.

### BACKGROUND ART

There is conventionally a proposal of a power generating system for generating electric power with a thermoelectric conversion module by utilizing waste heat generated by an industrial furnace (Patent Document 1). This power generating system is the one wherein a cooling plate as a heat receiving surface on a low-temperature side of the thermoelectric conversion module is attached on a bulkhead of a water-cooling jacket placed outside a cooling room of a continuous furnace, and a heat receiving surface on a high-temperature side of the thermoelectric conversion module is placed not to contact a work which is a heat source and receives radiant heat from the work passing inside the cooling room after being sintered in a heat maintaining room so as to generate electric power. As shown in FIG. 16 for instance, in this power generating system, a thermoelectric conversion module 100 has alternately arranged a plurality of pairs of P-type thermoelectric elements 101a and N-type thermoelectric elements 101b electrically coupled in series by electrodes 102, and is attached on a bulkhead 105 of the water-cooling jacket via an electrical insulating cooling plate 104. To prevent destruction of the thermoelectric elements by thermal stress, the high-temperature side of the thermoelectric conversion module 100 is installed separately from the heat source while configuring an electrode portion for connecting the electrodes 102 of the thermoelectric elements on the high-temperature side mutually with a wire 103 and thereby allowing free movement of the thermoelectric elements 101a and 101b on the high-temperature side. Furthermore, the heat receiving surface on the high-temperature side is covered with a large number of heat collecting plates 106 made of black bodies which are appropriately divided to receive the radiant heat easily. Reference numeral 106 in FIG. 16 denotes a moving heat source, and 107 denotes a coolant as a cooling source.

Patent Document 1: Japanese Patent Laid-Open No. 2002-171776

In the case of generating electric power with the thermoelectric conversion modules by utilizing the work moving while gradually lowering temperature as the heat source as shown in Patent Document 1, however, the radiant heat received by the heat receiving surface of the thermoelectric conversion module is significantly different by thermoelectric conversion module or by part of the heat receiving surface. Thus, there is a problem that it is impossible to strike a balance between increasing utilization of waste heat and increasing output of power generation.

To be more specific, it is desirable, from a viewpoint of effectively using the waste heat, to install the thermoelectric conversion module in proximity to an entrance of a cooling zone of the highest heat source temperature. Depending on the heat source temperature, however, there is a possibility that a maximum working temperature of the thermoelectric conversion module may be exceeded. The maximum working temperature of the thermoelectric conversion module is dependent on an operative temperature decided by a material of the thermoelectric semiconductor, a melting point of a joining material such as a brazing filler metal or an adhesive used on assembly of the thermoelectric conversion module, and the like. In the case of using a BiTe as a thermoelectric semiconductor for instance, the maximum working temperature is 220° C. or so. In the case of using a FeSi, the maximum working temperature is 700° C. or so. And in the case of using a SiGe, the maximum working temperature is 1000° C. or so. The melting point of a joining material such as a brazing filler metal or an adhesive should be higher than the working temperature of the thermoelectric conversion module and lower than the melting point of the thermoelectric semiconductor. For this reason, if the thermoelectric conversion module is heated over the maximum working temperature of the thermoelectric conversion module 100, there is a possibility that the joining material melts and the thermoelectric conversion module gets damaged.

On a downstream side of the cooling zone, the temperature of the heat source itself is reduced while the heat source passes inside the cooling zone. Therefore, a loadable temperature difference for the thermoelectric conversion module becomes small, and output of the thermoelectric conversion module is also reduced. Generally, the output of the thermoelectric conversion module is substantially in proportion to the square of the temperature difference which the thermoelectric semiconductor is loaded with. Therefore, an output difference per thermoelectric conversion module between upstream and downstream of the cooling zone is very large.

Thus, the thermoelectric conversion module can give its best performance only in an area upstream of the cooling zone and not exceeding the maximum working temperature of the thermoelectric conversion module. Further downstream, it can only give performance several times or several tens of times lower than that. For this reason, the thermoelectric conversion module covered with the heat collecting plates made of black bodies can be installed only in the area in a temperature range where the heat receiving surface of the thermoelectric conversion module is not exceeding and not significantly lower than the maximum working temperature. Therefore, use of the waste heat is not efficient enough, which is not desirable in view of reduction in equipment cost and unit cost of power generation. Thus, it has been difficult to construct a power generating system so as to obtain maximum output with the thermoelectric conversion module by using as the heat source the waste heat generated by the industrial furnace having the cooling zone involving the waste heat such as a sintering furnace.

As for a thermoelectric conversion system constructed by including the thermoelectric conversion module, it is important, not only in the case of utilizing the waste heat of the sintering furnace, to keep the temperature of the thermoelectric conversion module as close to the maximum working temperature as possible without having an upper limit of the working temperature exceeded in order to obtain the maximum output as the thermoelectric conversion system. In the case where a quantity of heat received from the heat source is not even on the entire heat receiving surface of the thermoelectric conversion module, however, there is a problem that power generation efficiency deteriorates at a low-temperature location if the thermoelectric conversion system is constructed according to the maximum temperature, and the thermoelectric conversion module gets damaged at a high-temperature location if the thermoelectric conversion system is constructed according to the minimum temperature.

Thus, an object of the present invention is to provide the thermoelectric conversion system and an efficiency improving method of the thermoelectric conversion system, in which a heat quantity to be input to the thermoelectric conversion module is limited to the maximum working temperature or less to keep soundness of the thermoelectric conversion module and the thermoelectric conversion module is actuated at the temperature as close to the maximum working temperature as possible to attain a large collective output and improve its economic efficiency.

### DISCLOSURE OF THE INVENTION

To attain the object, a thermoelectric conversion system according to the present invention is the system including at least one thermoelectric conversion module including at least a pair of thermoelectric elements, a heat receiving zone for receiving heat by radiation from a heat source and a radiating zone positioned on an opposite side to the heat receiving zone and cooled by a coolant, generating electric power by a temperature difference between the heat receiving zone and the radiating zone, a continuous or divided heat receiving surface formed by one or a plurality of surfaces facing the heat source of the heat receiving zone, and each of the heat receiving surface given a different quantity of heat from the heat source, the system comprising the heat receiving surface having a plurality of different emissivities according to the quantity of heat received from the heat source.

An efficiency improving method of the thermoelectric conversion system according to the present invention is the method including at least one thermoelectric conversion module including at least a pair of thermoelectric elements, a heat receiving zone for receiving heat by radiation from a heat source and a radiating zone positioned on an opposite side to the heat receiving zone and cooled by a coolant, generating electric power by a temperature difference between the heat receiving zone and the radiating zone, a continuous or divided heat receiving surface formed by one or a plurality of surfaces facing the heat source of the heat receiving zone, and each of the heat receiving surfaces given a different quantity of heat from the heat source, the method comprising an emissivity of each of the heat receiving surfaces adjusting to a different value according to a quantity of heat received from the heat source to limit a heat quantity to be input to the thermoelectric conversion module to a maximum working temperature or less and to actuate the thermoelectric conversion module at a temperature close to the maximum working temperature so as to enhance a collective output.

As the emissivity becomes lower, the heat receiving surface becomes less heat-absorbing and the thermoelectric conversion module becomes less heatable. Inversely, as the emissivity becomes higher, the heat receiving surface becomes more heat-absorbing and the thermoelectric conversion module becomes more heatable. Therefore, the heat receiving surface for receiving a large quantity of heat from the heat source should have low emissivity so that the heat receiving surface can become less heatable so as to limit a heating temperature of the thermoelectric conversion module to the maximum working temperature or less and keep soundness of the thermoelectric conversion module. Furthermore, as the temperature difference between the heat receiving surface and a cooling surface becomes larger, high power generation efficiency can be attained. The heat receiving surface for receiving a small quantity of heat from the heat source should have high emissivity so that the heat receiving surface can become more heatable so as to keep the heating temperature of the thermoelectric conversion module close to the maximum working temperature and attain high power generation efficiency by increasing the temperature difference between the heat receiving surface and the cooling surface.

It is desirable to set the emissivity of the heat receiving surface of the thermoelectric conversion system of the present invention at a target value by selecting a material configuring the heat receiving surface, selecting one or a plurality of covering materials for covering part or all of the material or adjusting surface roughness of the heat receiving surface or by combining these. In this case, it is possible to adjust the emissivity of the heat receiving surface to an optimal value easily by selecting the material configuring the heat receiving surface or a state of finish of the heat receiving surface. Thus, it is possible to limit the quantity of the heat input to the thermoelectric conversion module to the maximum working temperature or less, keep soundness of the thermoelectric conversion module and actuate the thermoelectric conversion module at a temperature as close to the maximum working temperature as possible. Here, the emissivity of the heat receiving surface can be different module by module or partially within one heat receiving surface.

It is desirable to form the heat receiving surface of the thermoelectric conversion system of the present invention by arranging two or more materials and two or more covering materials having different emissivities or one or more covering materials and a base of the material configuring a heat receiving plate, or the surface roughness adjusted to 2 or more, and materials or covering materials having different emissivities, and arbitrary surface roughness in combination. In this case, it is preferable to form the heat receiving surface by regularly arranging these combinations. And it is further preferable to have rows of the materials, covering materials and surface roughness having different emissivities existent in a projection plane of thermoelectric elements on the heat receiving surface. In this case, the emissivity as the heat receiving surface is almost equal to an average of the emissivities of the materials configuring the heat receiving surface, and a target emissivity can be obtained even in the case where the material of a required emissivity is not available.

According to the thermoelectric conversion system of the present invention, it is desirable to select thermoelectric elements of a high operative temperature as the thermoelectric elements applied to the heat receiving surface given a large quantity of heat from the heat source while selecting thermoelectric elements of a low operative temperature as the thermoelectric elements to the heat receiving surface given a small quantity of heat from the heat source. In this case, it is possible to actuate the thermoelectric conversion module with higher power generation efficiency.

According to the thermoelectric conversion system of the present invention, the heat source is a moving heat source. The thermoelectric conversion module is provided along a movement path of the moving heat source, and the emissivity of the heat receiving surface on an upstream side of the movement path is set lower than the emissivity of the heat receiving surface on a downstream side of the movement path.

Therefore, the heat receiving surface opposed to the heat source on an upstream side of the movement path for generating a quantity of heat large enough to heat the thermoelectric conversion module to the maximum working temperature and over should have low emissivity so that the heat receiving surface can become less heatable so as to limit a heating temperature of the thermoelectric conversion module to the maximum working temperature or less and keep soundness of the thermoelectric conversion module. Furthermore, as the temperature difference between the heat receiving surface and a cooling surface becomes larger, high power generation efficiency can be attained. The heat receiving surface opposed to the heat source on a downstream side of the movement path for generating a smaller quantity of heat should have high emissivity so that the heat receiving surface can become more heatable so as to keep the heating temperature of the thermoelectric conversion module close to the maximum working temperature and attain high power generation efficiency by increasing the temperature difference between the heat receiving surface and the cooling surface.

According to the thermoelectric conversion system of the present invention, the moving heat source is a work moving from a heating zone to the cooling zone inside a muffle of a sintering furnace. A cooling jacket is provided around the muffle in the cooling zone, and the thermoelectric conversion module is installed along the movement path inside the muffle in the cooling zone. Therefore, it is possible to perform efficient power generation by utilizing waste heat in the cooling zone of the sintering furnace, which is conventionally difficult to put into practical use.

According to the thermoelectric conversion system and the efficiency improving method of the thermoelectric conversion system of the present invention, the system comprises the heat receiving surface having adequate a plurality of emissivities according to the quantity of heat received from the heat source. Thus, it is possible to limit the quantity of the heat input to the thermoelectric conversion module to the maximum working temperature or less, keep soundness of the thermoelectric conversion module and actuate the thermoelectric conversion module at a temperature as close to the maximum working temperature as possible. To be more specific, even in an area of a heat source temperature exceeding the maximum working temperature on the heat receiving surface covered with black bodies, low emissivity is set so that the heat receiving surface can become less heatable so as to limit a heating temperature of the thermoelectric conversion module to the maximum working temperature or less and keep soundness of the thermoelectric conversion module. At the same time, on the heat receiving surface for receiving a small quantity of heat from the heat source, high emissivity is set so that the heat receiving surface can become more heatable so as to keep the heating temperature of the thermoelectric conversion module close to the maximum working temperature and attain high power generation efficiency by increasing the temperature difference between the heat receiving surface and the cooling surface. Thus, the thermoelectric conversion system can increase utilization of the waste heat and attain a large power generation quantity so as to improve its economic efficiency.

According to the thermoelectric conversion system of the present invention, it is further possible to select the emissivity appropriately out of a variety of materials by selecting the materials and covering materials configuring the heat receiving surface or adjusting the surface roughness of the heat receiving surface or the like. In the case where the material of a required emissivity is nevertheless unavailable, it is possible to easily adjust the emissivity of the heat receiving surface to the optimal value, limit the quantity of the heat input to the thermoelectric conversion module to the maximum working temperature or less, keep soundness of the thermoelectric conversion module and actuate the thermoelectric conversion module at a temperature as close to the maximum working temperature as possible.

Furthermore, the heat receiving surface of the thermoelectric conversion system of the present invention can obtain an arbitrary emissivity by combining materials or covering materials having different emissivities or selecting the surface roughness. Therefore, it is possible to have different emissivities on the entire heat receiving surface or in part of one heat receiving surface. The emissivity of the entire heat receiving surface is almost equal to an average of the emissivities of the materials configuring the heat receiving surface, and a target emissivity can be obtained even in the case where the material of a required emissivity is not available. As the heat receiving surface of the present invention is formed by regularly arranging the combinations of a plurality of materials, covering materials and the like, irregularity of the emissivity is reduced on the entire heat receiving surface. Furthermore, the heat receiving surface of the present invention has unit sizes of the materials, covering materials and surface roughness having different emissivities to be combined, smaller than area of the thermoelectric element contacting the heat receiving surface. Therefore, there are no variations in temperature chip by chip of a thermoelectric semiconductor.

Furthermore, the thermoelectric conversion system according to the present invention comprises the thermoelectric elements having different operative temperatures according to the quantity of heat received from the heat source in conjunction with optimization of the emissivity. Therefore, it is possible to prevent the thermoelectric conversion module from exceeding an upper limit of the working temperature against a higher-temperature heat source and keep the heating temperature of the thermoelectric conversion module close to the maximum working temperature against a lower-temperature heat source so as to actuate the thermoelectric conversion module with higher power generation efficiency.

Furthermore, the thermoelectric conversion system can perform efficient power generation by utilizing the waste heat generated in the cooling zone of the sintering furnace, which allows practical application of the power generation utilizing the waste heat generated in the cooling zone of the sintering furnace.

### BRIEF DESCRIPTION OF THE DRAWINGS

FIG. 1 is a side view of a sintering furnace showing an example of an embodiment of a thermoelectric conversion system of the present invention applied to the sintering furnace;

FIG. 2 is a sectional view of a cooling zone of the sintering furnace viewed from a front thereof;

FIG. 3 is a schematic block diagram of the sintering furnace;

FIG. 4 is a graph showing a relation between a temperature of a work and a moving direction position of the work in the sintering furnace;

FIG. 5 is a block diagram showing a configuration example of a thermoelectric conversion module;

FIG. 6 is a block diagram showing another configuration example of the thermoelectric conversion module;

FIG. 7 is a block diagram showing a further configuration example of the thermoelectric conversion module;

FIG. 8 is a block diagram showing a still further configuration example of the thermoelectric conversion module;

FIG. 9 is a top view showing an example of a method of setting an emissivity of a heat receiving surface;

FIG. 10 is a top view showing another method of setting the emissivity of the heat receiving surface;

FIG. 11 is a top view showing a further method of setting the emissivity of the heat receiving surface;

FIG. 12 show the cases where a different quantity of heat from the heat source is given to each of the heat receiving surface, where (A) shows the case where a heat source moves to the heat receiving surface, (B) shows the case where distances between the heat source and points on the heat receiving surface are different, and (C) shows the case where temperature distribution of the heat source itself is uneven;

FIG. 13 is a graph showing a difference in change of a heat receiving surface temperature and a heat source temperature as to an example of the present invention and a comparison example;

FIG. 14 is a block diagram showing another configuration example of a thermoelectric conversion module;

FIG. 15 is a block diagram showing a further configuration example of the thermoelectric conversion module; and

FIG. 16 is a block diagram showing a configuration example of a conventional thermoelectric conversion module.

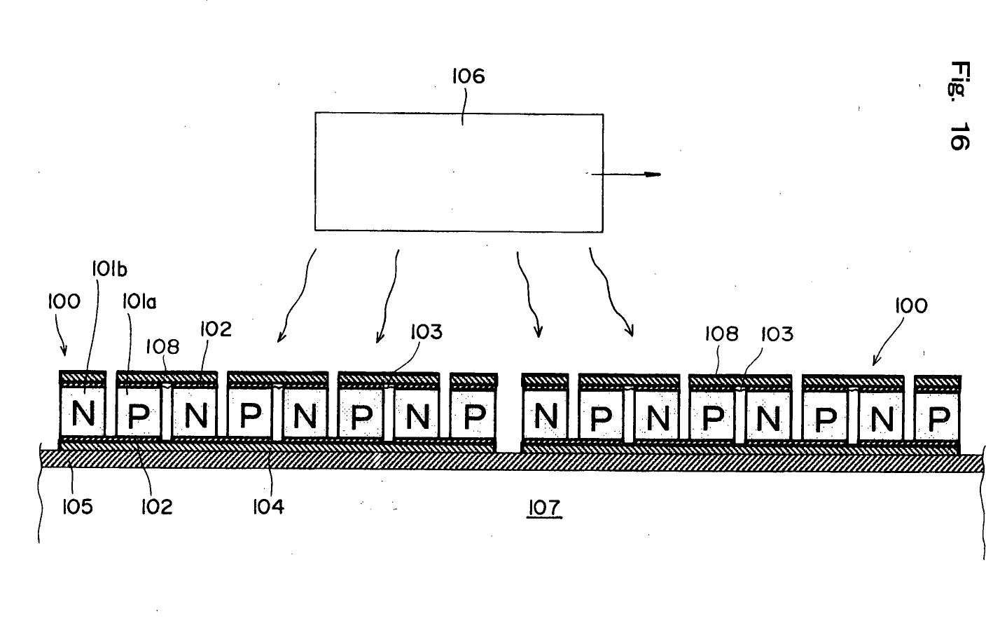

### DESCRIPTION OF SYMBOLS

1 Thermoelectric conversion system
2 Thermoelectric element
3 Heat source, work, graphite box
4 Coolant
5 Thermoelectric conversion module
6 Heat receiving zone
61 Heat receiving plate
7 Radiating zone
71 Cooling plate
7a Cooling surface
8 Sintering furnace
9 Muffle
9a Preheat zone
9b Sintering zone
9c Cooling zone
11 Cooling jacket
18 Heat receiving surface

### BEST MODE FOR CARRYING OUT THE INVENTION

A configuration of the present invention will be described in detail below based on an embodiment shown in the drawings.

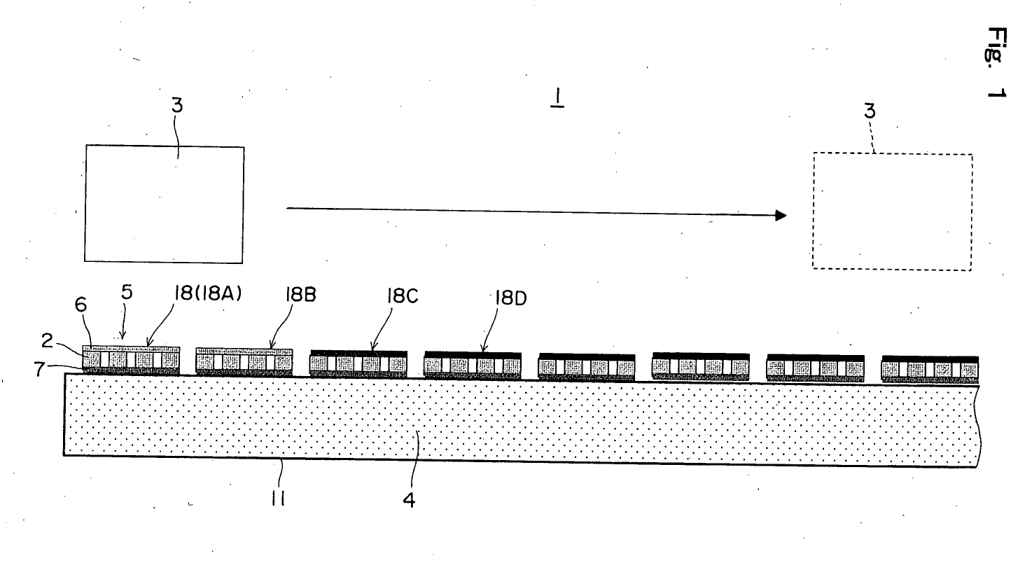

FIGS. 1 to 12 show an embodiment of a thermoelectric conversion system and an efficiency improving method of the thermoelectric conversion system of the present invention. This thermoelectric conversion system 1 comprises at least one thermoelectric conversion module 5, a heat source 3 for heating a high-temperature side heat receiving surface 18 of the thermoelectric conversion module, and a cold source (coolant) 4 for cooling a low-temperature side heat receiving surface 7a of the thermoelectric conversion module, where the heat receiving surface 18 of the thermoelectric conversion module 5 is heated by radiant heat from the heat source 3. The thermoelectric conversion module 5 comprises at least a pair of thermoelectric elements 2, a heat receiving zone 6 placed as the high-temperature side heat receiving surface 18 of the thermoelectric elements 2 not to contact the heat source 3 and receiving heat from the heat source 3 by radiation, and a radiating zone 7 placed as the low-temperature side heat receiving surface 7a of the thermoelectric elements 2 to contact the cold source and cooled by the coolant 4, where electric power is generated by a temperature difference generated between the heat receiving zone 6 and the radiating zone 7. The thermoelectric conversion system 1 is suitably used under conditions where the radiant heat is not equally given to the high-temperature side heat receiving surfaces of all the thermoelectric conversion modules but a quantity of the radiant heat received from the heat source 3 is partially (part by part) different as to each individual thermoelectric conversion module or the heat receiving surface of each individual thermoelectric conversion module, where different a plurality of emissivities are provided according to the quantity of heat received from the heat source 3 by the heat receiving surface 18 not contacting the heat source of the thermoelectric conversion module 5.

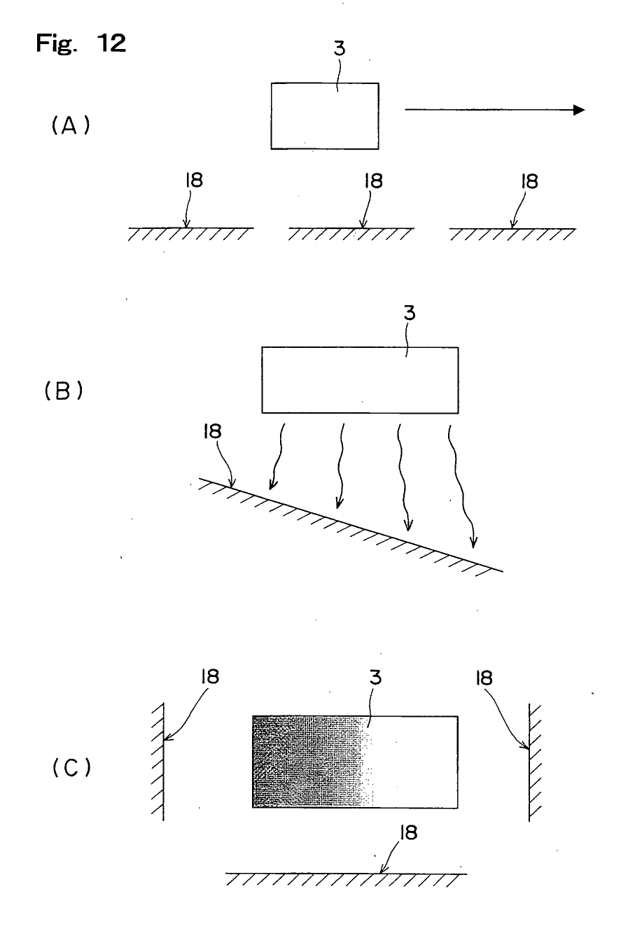

As for the cases where a different quantity of heat is given from the heat source 3 to each individual thermoelectric conversion module or each part of the heat receiving surface of each individual thermoelectric conversion module, for example, there are the thinkable cases where the heat source 3 moves to the heat receiving surface 18 as shown in FIG. 12 (A), distances between the heat source 3 and points on the heat receiving surface 18 are different as shown in FIG. 12 (B), and temperature distribution of the heat source 3 itself is uneven as shown in FIG. 12 (C). The present invention is applicable to any of these cases. The heat source 3 of FIG. 12 (C) indicates that the temperature becomes higher as the color becomes darker.

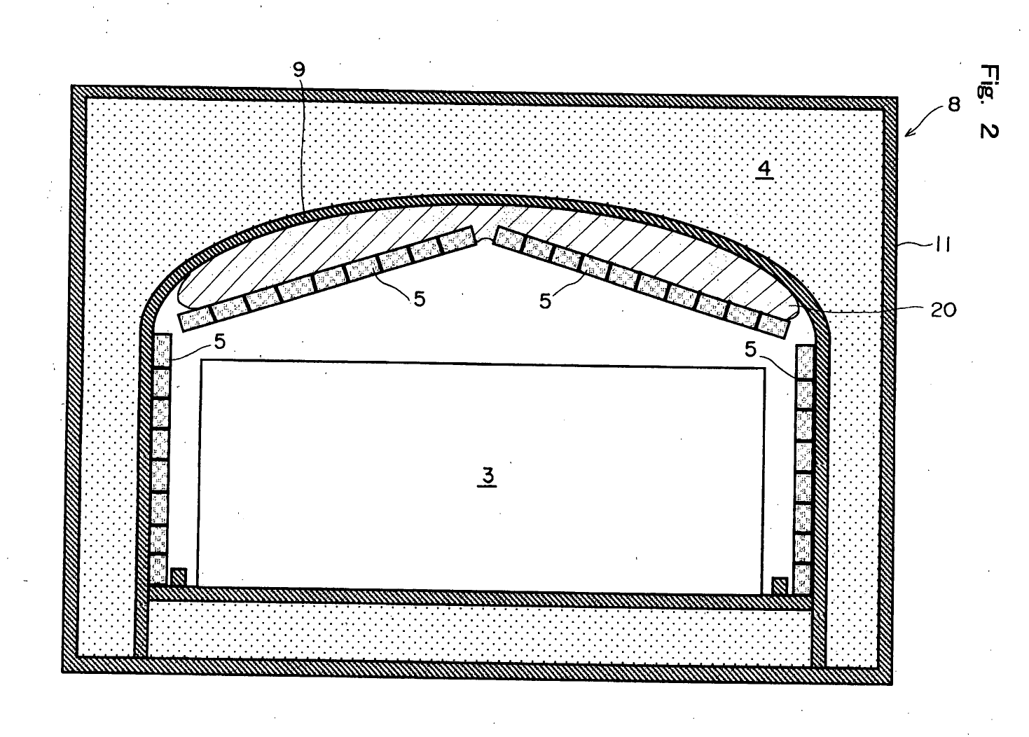

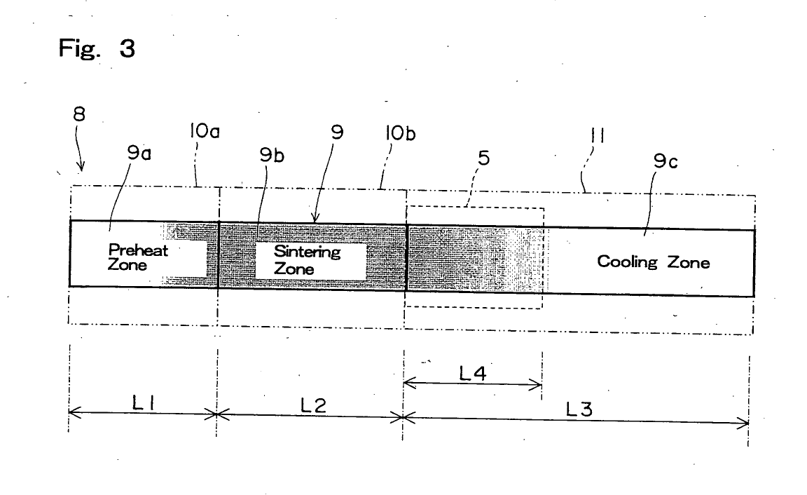

According to this embodiment applied to a sintering furnace for instance, the heat source 3 is a moving heat source, where the temperature of the heat source itself lowers as it moves downstream. The thermoelectric conversion module 5 is provided along a movement path of the moving heat source 3, and the emissivity of the heat receiving surface 18 on an upstream side of the movement path is set lower than the emissivity of the heat receiving surface 18 on a downstream side of the movement path. The moving heat source 3 is a work for moving from a heating zone to a cooling zone inside a muffle 9 of a sintering furnace 8 for instance. To be more specific, the work 3 is a graphite box housing a sintering product. A sintering furnace 8 includes the tunnel-like muffle 9 as shown in FIG. 2 for instance. The muffle 9 is axially divided into a preheat zone 9a, a sintering zone 9b and a cooling zone 9c as shown in FIG. 3. The preheat zone 9a and the sintering zone 9b have heating apparatuses 10a and 10b such as an electric heater or a gas heating jacket with a burner provided around the muffle 9. The cooling zone 9c has a cooling jacket 11 provided around the muffle 9. For instance, the cooling jacket 11 further covers the muffle 9 made of stainless steel around with an outer shell made of stainless steel to form space for letting the coolant 4 flow between the outer shell and the muffle 9. Cooling water is used as the coolant 4. The sintering products are put in the graphite boxes 3 and placed on a conveyer in the muffle 9 or pushed in one after another from an entrance side so as to pass inside the muffle 9 in order of the preheat zone 9a, sintering zone 9b and cooling zone 9c. Therefore, once the sintering product is put in, the graphite box 3 is heated by the preheat zone 9a and sintering zone 9b and cooled by the cooling zone 9c. The embodiment of FIG. 2 shows the case of mounting the thermoelectric conversion module on an existing sintering furnace. To mount the thermoelectric conversion module 5 in close contact, a grout of a well heat-conducting material such as a copper block 20 lies between a dome-shaped curved ceiling of the muffle 9 and the thermoelectric conversion module 5. As a matter of course, in the case where the ceiling of the muffle 9 is shaped like a spike or formed on a large flat surface and is suitable for directly mounting the cooling zone (cooling plate 71) 7 of the low-temperature side of the thermoelectric conversion module 5 in close contact, it is not always necessary to have the well heat-conducting grout lie between them.

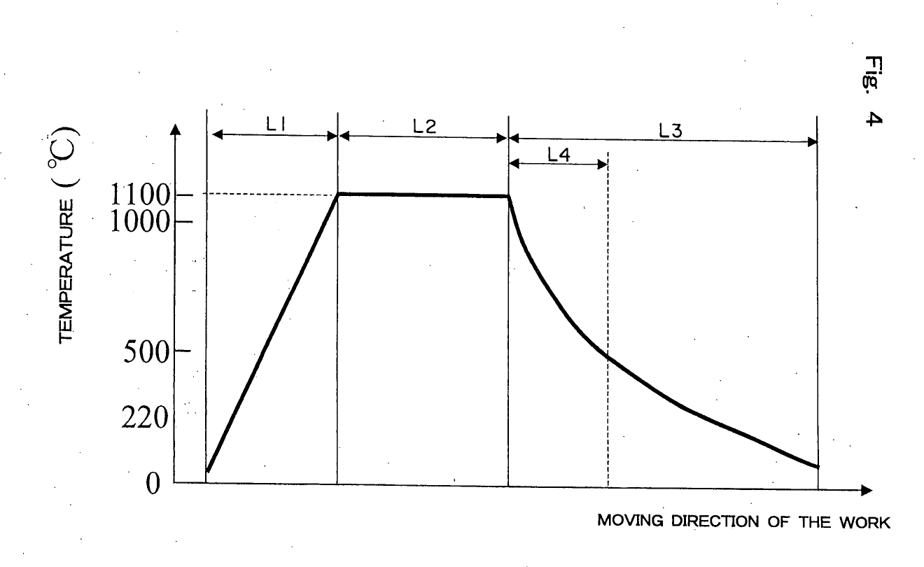

FIG. 4 shows an example of a relation between a moving direction position of the work 3 and a temperature of the work 3. In FIGS. 3 and 4, reference character L1 indicates axial length of the preheat zone 9a, L2 indicates the axial length of the sintering zone 9b, and L3 indicates the axial length of the cooling zone 9c. The thermoelectric conversion module 5 is installed along the movement path of the work 3 inside the muffle 9 in the cooling zone 9c. Reference character L4 in FIGS. 3 and 4 indicates the axial length of an area in which the thermoelectric conversion module 5 is installed. From a viewpoint of effectively using waste heat of the work 3, it is desirable to start an installation range L4 of the thermoelectric conversion module 5 from a location as close as possible to an exit of the sintering zone 9b, that is, the entrance of the cooling zone 9c where the temperature of the work 3 is high within the range capable of limiting the working temperature of the thermoelectric conversion module 5 to an upper limit temperature. It is also desirable to extend L4 as long as efficient power generation by the thermoelectric conversion module 5 is possible.

The graphite box as the heat source 3 heated by the preheat zone 9a and the sintering zone 9b moves from upstream to downstream of the cooling zone 9c along the thermoelectric conversion module 5 without contacting the thermoelectric conversion module 5. The thermoelectric conversion module 5 receives heat by radiation from the graphite box 3, and has its opposite-side surface 7a cooled by the cooling jacket 11. The thermoelectric conversion module 5 generates electric power by a temperature difference, that is, a heat drop between the heat receiving surface 18 and the cooling surface 7a, and the generated power is supplied to an electric storage device and power utilizing equipment via a power collecting line which is not shown.

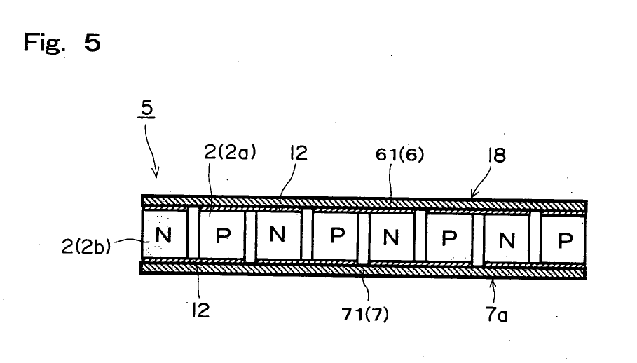

FIG. 5 shows a configuration example of the thermoelectric conversion module 5. The thermoelectric conversion module 5 includes alternately arranged a plurality of pairs of P-type thermoelectric semiconductors 2a and N-type thermoelectric semiconductors 2b, electrodes 12 for electrically connecting the adjacent P-type thermoelectric semiconductors 2a and N-type thermoelectric semiconductors 2b in series, an electrical insulating heat receiving plate 61 for covering the electrode 12 on the heat source 3 side and configuring the heat receiving zone 6, and the electrical insulating cooling plate 71 for covering the electrode 12 on the coolant 4 side and configuring the radiating zone 7. The heat receiving plate 61 and the cooling plate 71 are not particularly limited as to the material as long as it is heat-conducting. It is desirable, however, that the material should have good heat conductance. In many cases, the heat receiving plate 61 and the cooling plate 71 are composed of a metal. As the case may be, they may also be composed of an electrical insulating material such as ceramics doubling as an electrical insulating layer. In the case of the heat receiving plate 61 and the cooling plate 71 which are metallic, an insulating layer is formed between them and the electrodes 12. The heat receiving plate 61, the electrodes 12, thermoelectric elements 2 and cooling plate 71 are connected by a joining material such as a brazing filler metal or an adhesive so as to assemble the thermoelectric conversion module 5. The cooling surface 7a of the thermoelectric conversion module 5 is firmly fixed by the joining material such as an adhesive on the inner surface of the muffle 9 as a bulkhead for dividing the heat source 3 and the coolant 4. In the case where the inner surface of the muffle 9 is composed of the electrical insulating material, it is possible to do without the cooling plate 71. In this case, the electrode 12 on the coolant 4 side functions as the radiating zone 7.

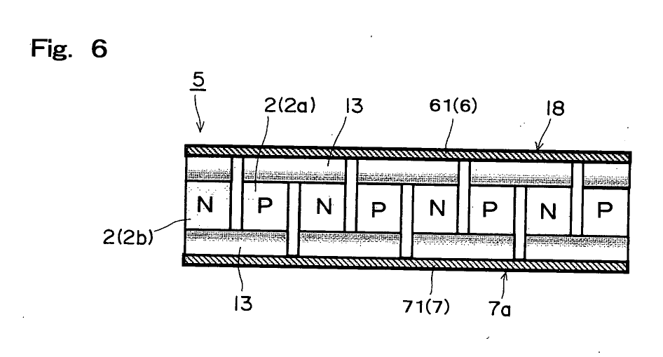

FIG. 6 shows another configuration example of the thermoelectric conversion module 5. The thermoelectric conversion module 5 includes alternately arranged a plurality of pairs of P-type thermoelectric semiconductors 2a and N-type thermoelectric semiconductors 2b, an FGM compliant pad 13 for electrically connecting the adjacent P-type thermoelectric semiconductors 2a and N-type thermoelectric semiconductors 2b in series, a heat receiving plate 61 for covering the FGM compliant pad 13 on the heat source 3 side and configuring the heat receiving zone 6, and the cooling plate 71 for covering the FGM compliant pad 13 on the coolant 4 side and configuring the radiating zone 7. The FGM compliant pad 13 forms an electrode layer on the thermoelectric element 2 side, and forms an electrical insulating layer on the heat receiving plate 61 side or the cooling plate 71 side. The FGM compliant pad 13 is a functionally gradient material (FGM) consisting of the electrode layer and electrical insulating layer, that is, the electrode layer on the thermoelectric element 2 side and the electrical insulating layer on the opposite side, where their composition continuously changes. It is possible, for instance, to utilize what is disclosed in Japanese Patent No. 3056047 and Japanese Patent No. 3482094. It is also possible to use the FGM compliant pad of which both surfaces consist of the electrode layers and inside consists of the electrical insulating layer. The heat receiving plate 61, FGM compliant pad 13, thermoelectric elements 2 and cooling plate 71 are connected by the joining material such as the brazing filler metal or the adhesive so as to assemble the thermoelectric conversion module 5. The cooling surface 7a of the thermoelectric conversion module 5 is firmly fixed by the joining material such as the brazing filler metal or the adhesive on the inner surface of the muffle 9 as the bulkhead for dividing the heat source 3 and the coolant 4. As the FGM compliant pad 13 itself is electrically insulating, it is possible to do without the cooling plate 71 whether or not the inner surface of the muffle 9 is composed of the electrical insulating material. In this case, the FGM compliant pad 13 on the coolant 4 side functions as the radiating zone 7.

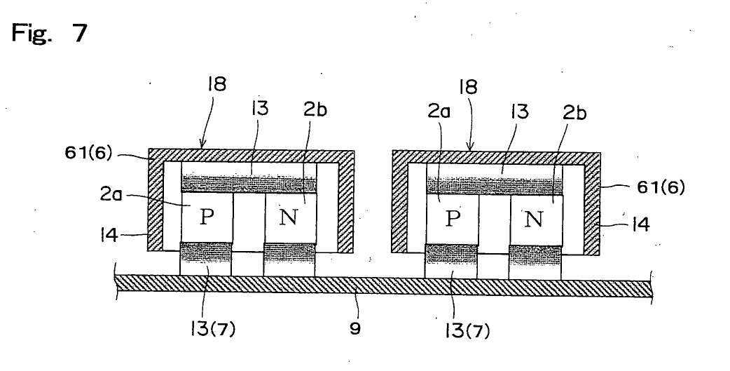

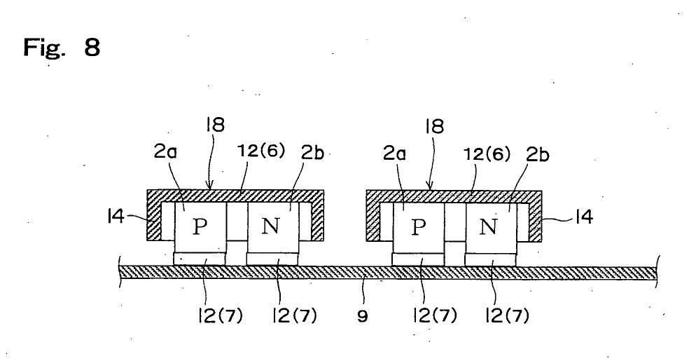

According to this embodiment, a plurality of thermoelectric conversion modules 5 shown in FIG. 5 or 6 are installed along the movement path of the work 3 inside the muffle 9 in the cooling zone 9c as shown in FIGS. 1 and 2. Therefore, there are a plurality of heat receiving surfaces 18 receiving heat by radiation from the work which is the heat source 3. In other words, the heat receiving surface 18 which receives heat by radiation from the work 3 is divided into a plurality. It is also possible, however, to have a configuration setting up only a single thermoelectric conversion module 5 having one large continuous heat receiving surface 18. In the case of the configuration of a single thermoelectric conversion module 5, there is a possibility that significant thermal stress may act on the heat receiving plate 61 due to the temperature distribution on the heat receiving surface 18. Therefore, it is desirable to form a slit on the heat receiving plate 61 and dissipate the thermal stress. It is also possible to finely divide the thermoelectric conversion module 5 into those having the thermoelectric elements 2 as minimum units, such as a uni-couple type comprising one piece each of the P-type thermoelectric semiconductor 2a and N-type thermoelectric semiconductor 2b. It is desirable to provide the heat receiving plate 61 from the viewpoint of enhancing mechanical strength of the thermoelectric conversion module 5 and facilitating handling during mounting work. It is also possible, however, to have the electrodes 12 and FGM compliant pad 13 on the heat source 3 side function as the heat receiving zone 6 without providing the heat receiving plate 61 in the case of finely dividing the thermoelectric conversion module 5 into the minimum units, and the like. Furthermore, in this case, the heat drop of the thermoelectric elements 2 decreases and the power generation efficiency lowers when the side faces of the thermoelectric elements 2 receive heat by radiation from the heat source 3. Therefore, it is desirable, as shown in FIGS. 7 and 8, to extend the heat receiving plate 61, the electrodes 12 or the FGM compliant pad 13 and provide skirt zones 14 for covering over the side faces of the thermoelectric elements 2.

As for the thermoelectric conversion system 1 of this embodiment in which the heat source 3 moves along a plurality of thermoelectric conversion modules 5 without contacting them while the thermoelectric conversion modules 5 receive heat by radiation from the heat source 3 and have the opposite surfaces 7a thereof cooled, the following formula indicates a quantity of heat Q_{Rad} transmitted from the heat source 3 to the heat receiving surface 18 of the thermoelectric conversion module 5 at a certain local point in a moving direction of the heat source 3.
Q_{Rad}=σ(T⁴−T₂⁴)/(1/ε₁+1/ε₂−1) <Formula 1>
Here:
σ: Staphan-Boltzmann constant=5.67×10⁻⁸ (W/m²K⁴)
T₁: Absolute temperature (K) of the heat source
T₂: Absolute temperature (K) of the heat receiving surface of the thermoelectric conversion module
ε₁: Emissivity of the heat source

ε₂: Emissivity of the heat receiving surface of the thermoelectric conversion module

A quantity of heat Q_{Con} flowing inside the thermoelectric conversion module 5 is acquired by the following formula.
Q_{Con}=(T₂−T₃)/R_{Total} <Formula 2>
Here:
T₂: Absolute temperature (K) of the heat receiving surface of the thermoelectric conversion module
T₃: Absolute temperature (K) of a coolant mainstream in a cooling duct
R_{Total}: Synthetic thermal resistance considering the thermal resistance of the thermoelectric conversion module and a heat transfer coefficient in the cooling duct

If dissipation of the heat to the side faces of the thermoelectric conversion module 5 is ignored, the above Q_{Rad} and Q_{Con} are equal. Therefore, given the absolute temperature T₁ of the heat source 3 on the most upstream side of the cooling zone 9c, that is, at an outlet of the sintering zone 9b in other words and the absolute temperature T₃ of the mainstream of the coolant 4 in the cooling jacket 11 on the most upstream side of the cooling zone 9c, that is, at an inlet of the cooling zone 9c in other words, simultaneous equations consisting of the formula 1 and formula 2 can be solved to acquire the quantity of heat flowing inside the thermoelectric conversion modules 5 in very small regions in a moving direction of the heat source 3 and the absolute temperature T₂ of the heat receiving surface 18 of the thermoelectric conversion module 5. This calculation is repeated as to each of the very small regions so as to acquire temperature history of T₁, T₂ and T₃ in the moving direction of the heat source 3. As for the heat receiving surface temperature T₂, it is possible to acquire the optimal value capable of keeping the soundness of the thermoelectric conversion module 5 and attaining high power generation efficiency by increasing the temperature difference between the heat receiving surface 18 and the cooling surface 7a as much as possible based on the maximum working temperature of the thermoelectric elements 2 and a melting point of a joining material such as an adhesive used on assembly of the thermoelectric conversion module 5. Once the optimal heat receiving surface temperature T₂ is acquired, it is possible to acquire the emissivity ε₂ of the heat receiving surface 18 capable of acquiring the optimal value T₂ based on the formula 1.

As the emissivity ε₁ of the heat source 3 is temperature-dependent to be exact, there is no significant change even though it changes a little as the heat source 3 moves from upstream to downstream of the cooling zone 9c. It is not possible, in any case, to change the emissivity ε₁ of the heat source 3 artificially in conjunction with the movement of the heat source 3 from upstream to downstream of the cooling zone 9c. On the other hand, it is possible to optimize the value of the emissivity 62 of the heat receiving surfaces 18 of a plurality of thermoelectric conversion modules 5 or the emissivity ε₂ of the zones of one heat receiving surface 18 of one thermoelectric conversion modules 5.

The emissivity depends on a surface finish state as well as the materials, and also depends on a degree of oxidation in the case of using it in the air. Therefore, the emissivity E2 of the heat receiving surface 18 can be set at a target value by selecting a material configuring the heat receiving surface 18, selecting one or a plurality of covering materials for covering part or all of the material configuring the heat receiving zone as a base or according to the surface finish state of the heat receiving surface 18, that is, a degree of surface roughness of the heat receiving surface 18. As a matter of course, it is also possible to set the emissivity ε₂ of the heat receiving surface 18 at the target value by combining all or part of the above-mentioned means. The covering materials can be attached on the surface of the material configuring the heat receiving zone as the base (referred to as a basis material) by means of coating, vapor deposition, plating, painting or attaching for instance. The emissivity can be decreased by rendering the heat receiving surface 18 as a mirror finish while it can be increased by rendering it as a rough finish having finely irregularities on the heat receiving surface 18.

Table 1 shows candidates of the materials for the heat receiving zone 6 and the covering materials for covering part or all of the heat receiving zone 6 of the thermoelectric conversion module 5. Table 2 shows referential emissivities of the materials. However, the materials shown in Tables 1 and 2 are the cases in point. The basis material configuring the heat receiving surface 18 of the present invention and the covering materials for covering the basis material are not limited thereto, and the material of the optimal emissivity can be selected out of a wide variety of materials other than these. The emissivity also depends on the degree of oxidation of atmosphere. Therefore, it is desirable to select the materials by considering whether the state of the atmosphere for using the thermoelectric conversion module 5 is oxidation atmosphere, reduction atmosphere or inert atmosphere.

TABLE 1

| | Atmosphere | | |
|---|---|---|---|
| | to be used | Low emissivity | High emissivity |
| Heat | Reduction | Alumina, Cu, Ni, | SiC, Carbon, |
| Receiving | atmosphere | Al (for low | Si₃N₄ |
| zone | | temperature) | |
| | Oxidation | Alumina, Zirconia, | Stainless steel (oxidation) |
| | atmosphere | Al (for low | Ni (oxidation) |
| | | temperature) | (*Surface oxidation) |
| Covering | Reduction | Alumina-dispersed | Graphite-dispersed heat- |
| material | atmosphere | adhesive, | resistant paint, |
| | | Zirconia-dispersed | SiC-containing ceramics |
| | | Adhesive | paint, CVD-SiC |
| | Oxidation | Alumina-dispersed | Graphite-dispersed heat- |
| | atmosphere | adhesive, | resistant paint |
| | | Zirconia-dispersed | (for low temperature), |
| | | adhesive | SiC-containing ceramics |
| | | | paint, CVD-SiC |

TABLE 2

| | Referential |
|---|---|
| Material | emissivity |
| Cu | 0.05-0.80 |
| Al | 0.09-0.40 |
| Ag | 0.04-0.10 |
| Alumina | 0.22-0.4 |
| Zirconia | 0.18-0.43 |
| Ni | 0.25-0.85 |
| SiC | 0.80-0.83 |
| Carbon | 0.90-0.95 |
| Si₃N₄ | 0.89-0.90 |
| Stainless steel surface oxidation | 0.85 |
| Ni surface oxidation | 0.37-0.48 |

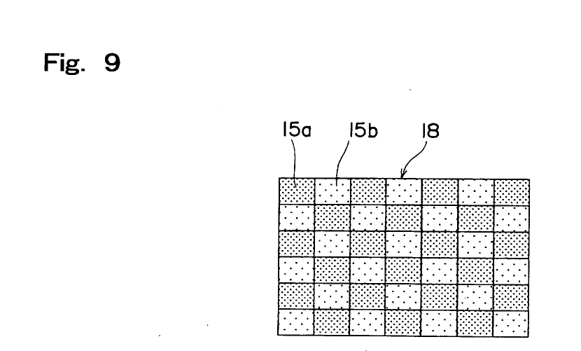

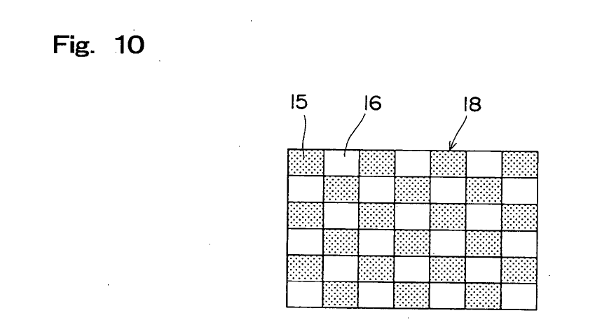

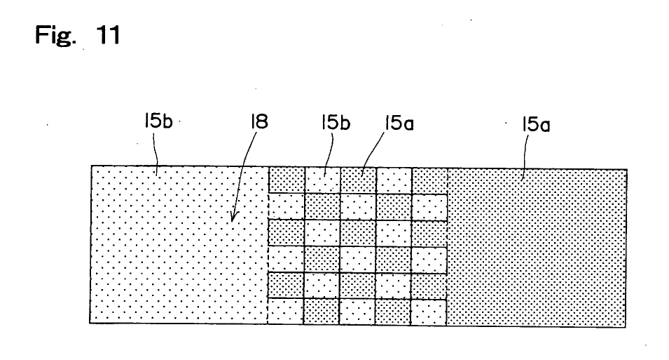

The coating material can be selected out of a wide variety of materials. In the case where the material of required emissivity is nevertheless unavailable, the heat receiving surface 18 may be formed by arranging and coating or attaching two or more materials of different emissivities on the heat receiving plate 61 or the electrodes 12 or FGM compliant pad 13 for functioning as the heat receiving zone 6 which is the base. As shown in FIG. 9 for instance, it is possible to arrange two covering materials 15a and 15b of different emissivities regularly and coat the heat receiving plate 61 therewith in a fine lattice pattern for instance so as to form the heat receiving surface 18. As shown in FIG. 10, it is also possible, by using the covering material 15 and a basis material 16 of different emissivities, to coat the heat receiving plate 61 with the basis material 16 and further coat it with the covering material 15 arranged finely and regularly by coating it in the lattice pattern for instance so as to form the heat receiving surface 18. In the case where the emissivities of the two materials configuring the heat receiving surface 18 are 0.2 and 0.4 for instance as a result of the coating in FIG. 9 or FIG. 10, it is possible to have almost the same effect as coating the entire heat receiving surface 18 with the material of which emissivity is 0.3. In this case, it is desirable to render the lattice pattern sufficiently finer than chip planar dimensions of the thermoelectric elements 2 so as to have no variations in temperature among chips of the thermoelectric elements 2 mounted on the same heat receiving surface 18. In other words, it is desirable to have rows of the materials having different emissivities existent in a projection plane of the thermoelectric elements 2 on the heat receiving surface 18. In the case of controlling the emissivity by combining the materials and covering materials having different emissivities or adjusting the surface roughness, it is possible, instead of being limited to configuring the heat receiving surface 18 by arranging the two materials regularly, to combine three or more materials or arranging such combinations and the like irregularly. In the case where the emissivity needs to be changed in one heat receiving surface 18 as shown in FIG. 11, that is, in the case of installing only a single thermoelectric conversion module 5 including one large continuous heat receiving surface 18 for instance, part of the heat receiving surface 18 may be coated in the lattice pattern. To be more specific, two or more materials of different emissivities are not always arranged regularly on the same entire surface. For instance, there may be the cases where a pattern on the heat receiving surface 18 formed by a plurality of materials gradually change or one heat receiving surface 18 is formed by three or more materials. It is also possible to coat an upstream end and a downstream end in the moving direction of the heat source of the heat receiving surface 18 with the covering materials of different emissivities or attach the materials of different emissivities thereto while coating the part between the ends with two or more covering materials of different emissivities or attaching two or more materials of different emissivities thereto so as to change the emissivity stepwise or sidlingly.

According to this embodiment, for instance, the heat receiving surface 18 located upstream of the cooling zone 9c given a large quantity of heat from the heat source 3 has a low emissivity. The emissivity of the heat receiving surface 18 becomes gradually higher as advancing downstream of the cooling zone 9c given a smaller quantity of heat from the heat source 3. For instance, the example of FIG. 1 indicates emissivity of a heat receiving surface 18A<emissivity of a heat receiving surface 18B<emissivity of a heat receiving surface 18C<emissivity of a heat receiving surface 18D. Here, the emissivity of the heat receiving surface 18 may increase either stepwise (in a staircase pattern) or continuously (a relation between the position from upstream to downstream of the cooling zone 9c and the emissivity of the heat receiving surface 18 at the position may be expressed by a direct or quadratic or higher function) from upstream to downstream of the cooling zone 9c. In the case of increasing the emissivity stepwise from upstream to downstream, length of sections of the same emissivity may be either the same or different. Here, in an area where the high-temperature side heat receiving surface temperature exceeds the maximum working temperature of the thermoelectric elements when set at the largest value by the materials capable of coating the heat receiving surface 18 or the materials configuring the heat receiving surface, it is desirable to render the emissivity of the heat receiving surface 18 at least lower than the aforementioned value so as to adjust the value of the high-temperature side heat receiving surface temperature not to exceed the maximum working temperature of the thermoelectric elements and get as close as possible to the maximum working temperature.

The lower the emissivity becomes, the less heat-absorbing the heat receiving surface 18 becomes and so the thermoelectric conversion module 5 becomes less heatable. Inversely, the higher the emissivity becomes, the more heat-absorbing the heat receiving surface 18 becomes and so the thermoelectric conversion module 5 becomes more heatable. Therefore, as for the heat receiving surface 18 opposed to the heat source 3 on the upstream side of the cooling zone 9c which generates the quantity of heat large enough to heat the thermoelectric conversion module 5 over the maximum working temperature, the emissivity should be low so that the heat receiving surface 18 becomes less heatable and heating temperature of the thermoelectric conversion module 5 is limited to the maximum working temperature or less to keep soundness of the thermoelectric conversion module 5 and attain high power generation efficiency by increasing the temperature difference between the heat receiving surface 18 and the cooling surface 7a. As for the heat receiving surface 18 opposed to the heat source 3 on the downstream side of the cooling zone 9c which generates a less quantity of heat, the emissivity should be higher than that of the heat receiving surface 18 on the upstream side of the cooling zone 9c to become more heatable so as to keep the heating temperature of the thermoelectric conversion module 5 close to the maximum working temperature and attain high power generation efficiency by increasing the temperature difference between the heat receiving surface 18 and the cooling surface 7a. In other words, it is possible to set a start position of the installation range L4 of the thermoelectric conversion module 5 closer to the inlet of the cooling zone 9c by lowering the emissivity of the heat receiving surface 18 on the upstream side of the cooling zone 9c. It is also possible to set the installation range L4 of the thermoelectric conversion module 5 longer by increasing the emissivity of the heat receiving surface 18 on the downstream side of the cooling zone 9c. Furthermore, it is possible to generate electric power by using the thermoelectric elements of which maximum working temperature is much lower than the case of using a heat collecting material made of a black body.

As described above, the heat receiving surface 18 having adequate a plurality of emissivities according to the quantity of heat received from the heat source 3 is formed so as to limit the heat quantity to be input to the thermoelectric conversion module 5 on the upstream side of the cooling zone of which heat source temperature is highest to the maximum working temperature or less, keep soundness of the thermoelectric conversion module 5 and actuate the thermoelectric conversion module 5 at the temperature as close to the maximum working temperature as possible on the downstream side of the cooling zone of which heat source temperature has lowered. Thus, the thermoelectric conversion system 1 can attain a large collective output and improve its economic efficiency.

Furthermore, in the case where the temperature of the heating zone configuring the heat receiving surface exceeds the maximum working temperature of the thermoelectric elements in use or hardly gets close to the maximum working temperature even by controlling the emissivity through selection of the coating material and change in the surface finish state, it is possible to cope with it by changing the thermoelectric elements at the same time. In the case of using a BiTe as the thermoelectric elements 2 for instance, the maximum working temperature is 220° C. or so. In the case of using a FeSi, the maximum working temperature is 700° C. or so. And in the case of using a SiGe, the maximum working temperature is 1000° C. or so. As for the thermoelectric conversion module 5 on the upstream side of the cooling zone 9c, the thermoelectric elements 2 of a high operative temperature are used, and the emissivity of the heat receiving zone 6 is lowered to be ready for the heat source of a higher temperature. As for the thermoelectric conversion module 5 on the downstream side of the cooling zone 9c, the thermoelectric elements 2 of a low operative temperature are used, and the emissivity is increased to allow the heat source of a lower temperature to get close to the maximum working temperature of the thermoelectric conversion module 5. Thus, the thermoelectric conversion system 1 can attain an even larger output and improve its economic efficiency (output/cost).

### EXAMPLE

A plurality of thermoelectric conversion modules 5 were installed along the movement path of the work 3 inside the muffle 9 in the cooling zone 9c of the sintering furnace 8 shown in FIGS. 1 to 4. The axial length L1 of the preheat zone 9a of the sintering furnace 8 is 3 m, the axial length L2 of the sintering zone 9b is 4 m, and the axial length L3 of the cooling zone 9c is 8 m. As shown in FIG. 4, the work (graphite box) 3 heated by the preheat zone 9a and sintering zone 9b is at 100° C. at the outlet of the sintering zone 9b, that is, the inlet of the cooling zone 9c. It is assumed that a main stream temperature of cooling water as the coolant 4 is 30° C. almost constantly. The reduction atmosphere is inside the muffle 9 of the cooling zone 9c. The thermoelectric elements of which maximum working temperature is 550° C. were used as the thermoelectric conversion modules 5, and the installation range L4 of the thermoelectric conversion modules 5 was 2.5 m from the inlet of the cooling zone. However, the range L4 for installing the thermoelectric conversion modules 5 is not limited to this example.

According to this example, the installation range L4 of the thermoelectric conversion modules 5 was divided equally into ten in the moving direction of the work, and the emissivity 62 of the heat receiving surface 18 of each of the areas was set as in the following Table 3. The heat receiving surface 18 of the thermoelectric conversion module 5 in the first area was composed of polished iron, the heat receiving surface 18 of the thermoelectric conversion module 5 in the second area was composed of nickel, the heat receiving surface 18 of the thermoelectric conversion module 5 in the third area was composed of brass, and the heat receiving surfaces 18 in the fourth to tenth areas were composed of oxidized iron.

TABLE 3

| | |
|---|---|
| First area (most upstream) | Emissivity 0.29 |
| Second area | Emissivity 0.41 |
| Third area | Emissivity 0.61 |
| Fourth to tenth areas | Emissivity 0.79 |

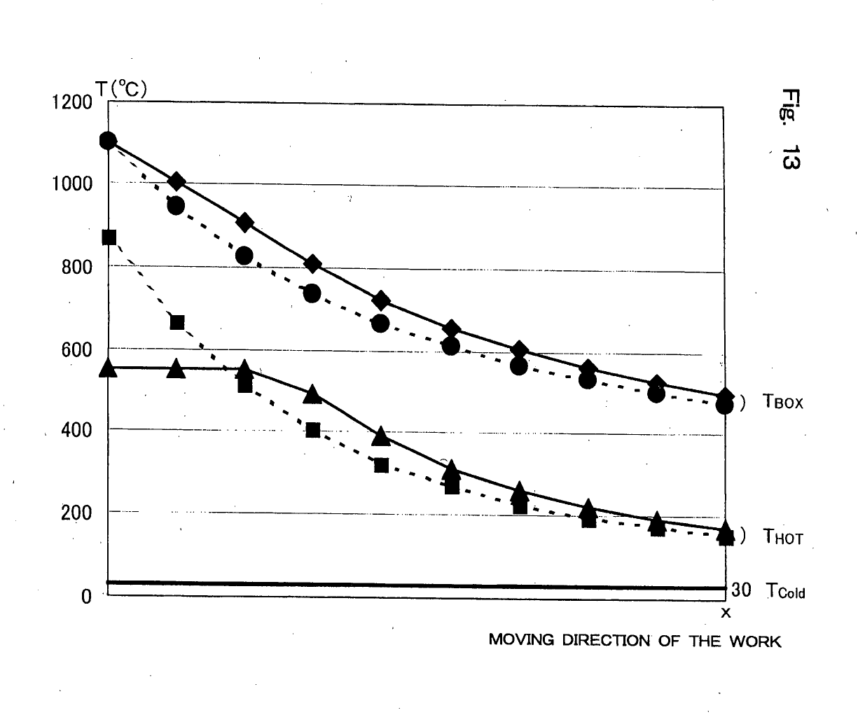

And measurements were made as to a temperature T_{BOX} of the work (graphite box) 3 and a temperature T_{HOT} of the heat receiving surfaces 18 of the thermoelectric conversion modules 5 of each of the areas divided into ten. As comparative examples, measurements were also made as to the work temperature T_{BOX} and the heat receiving surface temperature T_{HOT} in the case of configuring the heat receiving surfaces 18 of all the thermoelectric conversion modules 5 with the oxidized iron (emissivity 0.79). FIG. 13 shows the measurement results. A plot shown in full line and indicated by ♦ in FIG. 13 represents change of the work temperature T_{BOX} in the moving direction of the work in the example, and the plot shown in full line and indicated by ▴ in FIG. 13 represents the heat receiving surface temperature T_{HOT} of each of the areas in the example. The plot shown in broken line and indicated by ● in FIG. 13 represents change of the work temperature T_{BOX} in the moving direction of the work in the comparative example, and the plot shown in broken line and indicated by ▪ in FIG. 13 represents the heat receiving surface temperature T_{HOT} of each of the areas in the comparative example. T_{COLD} in FIG. 13 represents the main stream temperature of the cooling water.

As is clear from FIG. 13, in the comparative example, the heat receiving surface temperature T_{HOT} of the first and second areas exceeds the maximum working temperature 550° C. of the thermoelectric conversion module 5 so that the thermoelectric conversion module 5 may get damaged. In the example, the heat receiving surface temperature T_{HOT} of the first to third areas is held approximately to the maximum working temperature 550° C. of the thermoelectric conversion module 5. To be more specific, the heat receiving surfaces 18 of the thermoelectric conversion modules 5 are heated close to the maximum working temperature in the first to third areas upstream of the cooling zone 9c. Therefore, the thermoelectric conversion modules 5 in the first to third areas can give the best performance while keeping the soundness.

The heat receiving surface temperature T_{HOT} of the fourth area and onward in the example gradually lowers as it advances downstream of the cooling zone 9c. However, it is higher than that of the comparative example. The work temperature T_{BOX} of the example is also higher than that of the comparative example. This is supposedly because, in the case of this example, the emissivity of the heat receiving surfaces 18 of the thermoelectric conversion modules 5 on the upstream side (the first to third areas) of the cooling zone 9c is so low that the temperature of the work 3 is not lowered but kept high longer than the comparative example. To be more specific, it is possible, according to this example, to render the temperature difference between the heat receiving surfaces 18 and the cooling surfaces 7a on the downstream side of the cooling zone 9c larger than that of the comparative example. The output is approximately proportional to a square of the temperature difference with which the thermoelectric elements 2 are loaded. According to this example, the temperature difference with which the thermoelectric elements 2 are loaded from the fourth area onward increases by 10 percent against the comparative example, and the output is thereby estimated to increase by 20 percent. Therefore, power generation performance of the thermoelectric conversion module 5 from the fourth area onward is also improved by the present invention.

As described above, it has been verified that the present invention keeps the soundness of the thermoelectric conversion module 5 and also attains increase in the output as the thermoelectric conversion system 1 so as to improve the power generation performance.

The above-mentioned embodiment is an example of the preferred embodiment of the present invention. However, the present invention is not limited thereto but various changes may be made without departing from the scope of the invention. For instance, the present invention is not limited to moving the heat source 3 along the thermoelectric conversion module 5 as with the sintering furnace 8. It is also possible to fix the positional relation between the heat receiving surface 18 of the thermoelectric conversion module 5 and the heat source 3. If the quantity of heat received from the heat source 3 on a plurality of heat receiving surfaces 18 or each of the zones of one heat receiving surface 18 is acquired by calculation or measurement, it is possible to acquire an optimal emissivity on each of the zones of the heat receiving surface 18, that is, the optimal emissivity for limiting the amount of heat input to the thermoelectric conversion module to the maximum working temperature or less and actuate the thermoelectric conversion module at the temperature as close to the maximum working temperature as possible. The coolant 4 for cooling the cooling surface 7a of the thermoelectric conversion module 5 is not limited to the cooling water but the cooling surface 7a may also be cooled by natural convection of natural air.

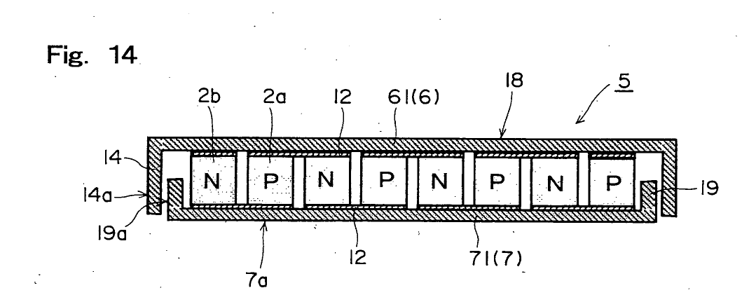

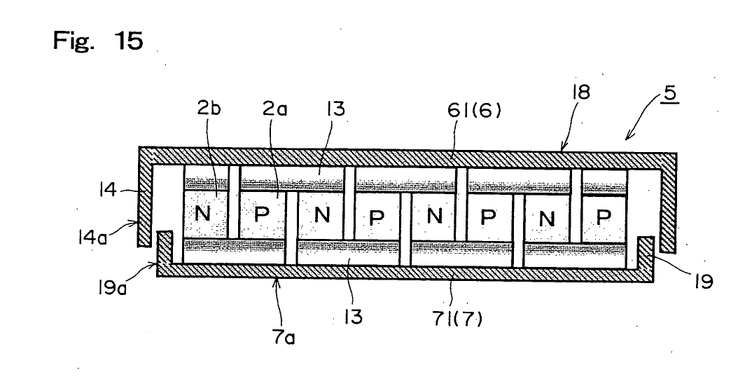

The examples shown in FIGS. 7 and 8 provide the skirt zones 14 for covering over the side faces of the thermoelectric elements 2 of the uni-couple type thermoelectric conversion modules 5. However, the skirt zones 14 may also be provided to the thermoelectric conversion modules 5 comprising a plurality of P-type thermoelectric semiconductors 2a and a plurality of N-type thermoelectric semiconductors 2b shown in FIGS. 5 and 6. As shown in FIGS. 14 and 15 for instance, the skirt zones 14 for covering over the side faces of the thermoelectric elements 2 may be provided by extending the heat receiving plate 61 and bending it toward the cooling surface 7a side. If a large gap is generated between the bulkhead (muffle 9) for dividing the heat source 3 and the coolant 4 and the skirt zones 14, there is a possibility that the side faces of the thermoelectric elements 2 may receive heat by radiation from the heat source 3 via this gap. Thus, it is possible, as shown in FIGS. 14 and 15 for instance, to extend the cooling plate 71 and bend it toward the heat receiving surface 18 side so as to provide a shielding zone 19 for covering over the side faces of the thermoelectric elements 2. The shielding zone 19 may also be provided to the uni-couple type thermoelectric conversion module 5 shown in FIGS. 7 and 8 as a matter of course. The skirt zones 14 and shielding zone 19 are not limited to those integral with the heat receiving plate 61 or the cooling plate 71, but the skirt zones 14 and shielding zone 19 as separate members may also be fixed to the heat receiving plate 61 or the cooling plate 71 by fixing means such as adhesion. Furthermore, it is desirable to render the emissivity of surfaces 14a and 19a of the skirt zones 14 and shielding zone 19, that is, the emissivity of the surfaces configuring the thermoelectric conversion module 5 as low as possible. To be more precise, the emissivity should desirably be that of the heat receiving surfaces 18 or less, more preferably below that of the heat receiving surfaces 18. Thus, the side faces of the thermoelectric conversion module 5 become less heatable so as to prevent the heat drop of the thermoelectric elements 2 from becoming small.

1: A thermoelectric conversion system including at least one thermoelectric conversion module including at least a pair of thermoelectric elements, a heat receiving zone for receiving heat by radiation from a heat source and a radiating zone positioned on an opposite side to the heat receiving zone and cooled by a coolant, generating electric power by a temperature difference between the heat receiving zone and the radiating zone, a continuous or divided heat receiving surface formed by one or a plurality of surfaces facing the heat source of the heat receiving zone, and each of the heat receiving surfaces given a different quantity of heat from the heat source, the system comprising the heat receiving surface having a plurality of different emissivities according to the quantity of heat received from the heat source.

2: The thermoelectric conversion system according to claim 1, wherein the emissivity of each heat receiving surface at a target value by selecting a basis material forming the heat receiving surface, selecting one or a plurality of covering materials for covering part or all of the basis material or a degree of surface roughness of the heat receiving surface or by combining part or all of these.

3: The thermoelectric conversion system according to claim 2, wherein the heat receiving surface is formed by arranging two or more materials having different emissivities.

4: The thermoelectric conversion system according to claim 3, wherein the heat receiving surface is formed by regularly arranging two covering materials having different emissivities, or one covering material and the basis material having different emissivities, and rows of the materials having different emissivities exist in a projection plane of the thermoelectric elements on the heat receiving surface.

5: The thermoelectric conversion system according to claim 1, wherein the thermoelectric elements of a high operative temperature are selected as the thermoelectric elements applicable to the heat receiving surface given a large quantity of heat from the heat source, and the thermoelectric elements of a low operative temperature are selected as the thermoelectric elements applicable to the heat receiving surface given a small quantity of heat from the heat source.

6: The thermoelectric conversion system according to claim 1, wherein the heat source is a moving heat source and the thermoelectric conversion module is provided along a movement path of the moving heat source, and the emissivity of the heat receiving surface on an upstream side of the movement path is set lower than the emissivity of the heat receiving surface on a downstream side of the movement path.

7: The thermoelectric conversion system according to claim 6, wherein the moving heat source is a work moving from a heating zone to a cooling zone inside a muffle of a sintering furnace, a cooling jacket is provided around the muffle in the cooling zone, and the thermoelectric conversion module is installed along the movement path of the work inside the muffle in the cooling zone.

8: An efficiency improving method of a thermoelectric conversion system including at least one thermoelectric conversion module including at least a pair of thermoelectric elements, a heat receiving zone for receiving heat by radiation from a heat source and a radiating zone positioned on an opposite side to the heat receiving zone and cooled by a coolant, generating electric power by a temperature difference between the heat receiving zone and the radiating zone, a continuous or divided heat receiving surface formed by one or a plurality of surfaces facing the heat source of the heat receiving zone, and each of the heat receiving surfaces given a different quantity of heat from the heat source, the method comprising an emissivity of each of the heat receiving surfaces adjusting to a different value according to a quantity of heat received from the heat source to limit a heat quantity to be input to the thermoelectric conversion module to a maximum working temperature or less and to actuate the thermoelectric conversion module at a temperature close to the maximum working temperature so as to enhance a collective output.
